(19) United States
(12) Patent Application Publication
(10) Pub. No.: US 2009/0001574 A1
(43) Pub. Date: Jan. 1, 2009

(54) Multi-chips Stacked package structure

(76) Inventors: Chun-fu FANG, Hsinchu city (TW); Ming-Hung Su, Hsinchu-city (TW); Yu-Ren Chen, Hsinchu-city (TW)

Correspondence Address: SINORICA, LLC, 528 FALLSGROVE DRIVE, ROCKVILLE, MD, 20850, US

(21) Appl. No.: 12/036,636

(22) Filed: Feb. 25, 2008

(30) Foreign Application Priority Data
Jun. 29, 2007 (TW) 096123628

(51) Int. Cl. H01L 23/538

(52) U.S. Cl. 257/738; 257/E23.169; 257/678

(57) ABSTRACT

A multi-chips Stacked package structure, wherein a plurality of chips are stacked on the substrate with a rotation so that a plurality of metallic ends and the metal pad on each chip on the substrate can all be exposed; a plurality of metal wires are provided for electrically connecting the plurality of metal pads on the plurality of chips with the plurality metallic ends on the substrate in one wire bonding process; then an encapsulate is provided for covering the plurality of stacked chips, a plurality of metal wires and the plurality of metallic ends on the substrate.

### BACKGROUND OF THE INVENTION

1. Field of the Invention

The present invention is related to a multi-chips stacked package structure, and more related to a multi-chips stacked package structure with a plurality of chips stacked on the substrate by a rotational angle.

2. Description of the Prior Art

In recent years, the semiconductor package process is using three-dimensional (3D) package method to have relative large integrated semiconductor or the volume of the memory in the less measure of area. In order to achieve this object, the chip stacked method is used to have 3D package structure.

In the prior art, the stacked method of the chips is used a plurality of chips to stack to each other on one substrate and the wire bonding process is used to electrically connect the chips and the substrate. FIG. 1A is a sectional view showing a chip stacked package structure with similar size of the chips in the prior art. As shown in FIG. 1A, the chip stacked package structure is showing that the first chip 18 is orthogonal to the second chip 28 and stacked on the substrate 12. And two edges of the first chip 18 and the second chip 28 include a plurality of bonding pads 26 and 36. Therefore, the wire bonding is used to electrically connect the bonding pads 26 and 36 on the first chip 18 and the second chip 28 with the substrate 12. If there are another chips will be stacked on the substrate 12, the process should wait until the wire bonding process of the first chip 18 and the second chip 28 was done. Therefore, another wire bonding process can be sued to electrically connect the other chips and the substrate 12. According the steps described above, it would waste the package time. Moreover, because the two chips are stacked and orthogonal to each other, the overlap area between two chips is small. Therefore, when the molding process is used in the package method, the adhesive area between two chips is not enough and the chips would be peeled off.

Besides, the FIG. 1B is showing a method that the upper chip 28 is rotated an angle (α) and stacked over the bottom chip 18. However, in the chips stacked package structure, a portion of the metal pads on the bottom chip was covered. Therefore, the wire bonding process for the bottom chip 18 is needed to finish first before another wire bonding process is started to electrically connect the upper chip 28 and the substrate 12. The package process is complicated and the package time is wasted.

### SUMMARY OF THE INVENTION

According to the drawbacks and the problems of prior art described above, there is a multi-chips stacked method is used in the present invention to stack the chips with similar size in a three-dimension package structure.

The main object of the present invention is to provide a multi-chips stacked package method to stack a plurality of chips with a rotational angle. Because each of the chips is rotated in an angle, a portion of the active surfaces between the upper and bottom chips are crossed to each other an the metal bonding pads on the active surface of each of the chips are exposed. Therefore, there is only one time wire bonding process used to electrically connect the chips and the substrate. The package time and cost are reduced.

Another object of the present invention is to provide a multi-chips stacked package structure in order to avoid the spacer using in the multi-chips stacked package structure to reduce the height of the stacked chips. Therefore, the package structure in the present invention includes higher package integration.

According the objects described above, the present invention includes a multi-chips stacked package structure comprising a substrate, a first chip, a second chip, a third chip, a forth chip, a plurality of conductive wires and an encapsulated material. The substrate comprises a top surface and a bottom surface. The top surface includes a plurality of metal terminals disposed thereon. The bottom surface includes a plurality of metal pads and each of the metal terminals is electrically connected to each of the metal pads. The first chip is connected in the center region of the top surface of the substrate by an adhesive layer and the end region of the top surface is exposed, and the longer two ends of the first chip include a plurality of bonding pads. The second chip is stacked on the first chip by the adhesive layer with a rotational angle and the metal pads of the first chip are exposed and the second chip includes a plurality of bonding pads. The third chip is stacked on the second chip by the adhesive layer with a rotational angle and the metal pads of the first chip and the second chip are exposed and the third chip includes a plurality of bonding pads. The forth chip is stacked on the third chip by the adhesive layer with a rotational angle and the metal pads of the first chip, the second chip and the third chip are exposed and the four chip includes a plurality of bonding pads. The conductive wires are used to electrically connect the bonding pads of the first chip, the second chip, the third chip and the forth chip and the metal terminals. The encapsulated material is used to cover the conductive wires on the first chip, the second chip, the third chip and the forth chip and the surface of the substrate.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A and FIG. 1B are views in prior art.

FIG. 2A and FIG. 2B are top view and sectional view of the chip in the present invention.

FIG. 3 is a top view showing an embodiment of the present invention.

FIG. 4 is a top view showing another embodiment of the present invention.

FIG. 5 is a top view showing one another embodiment of the present invention.

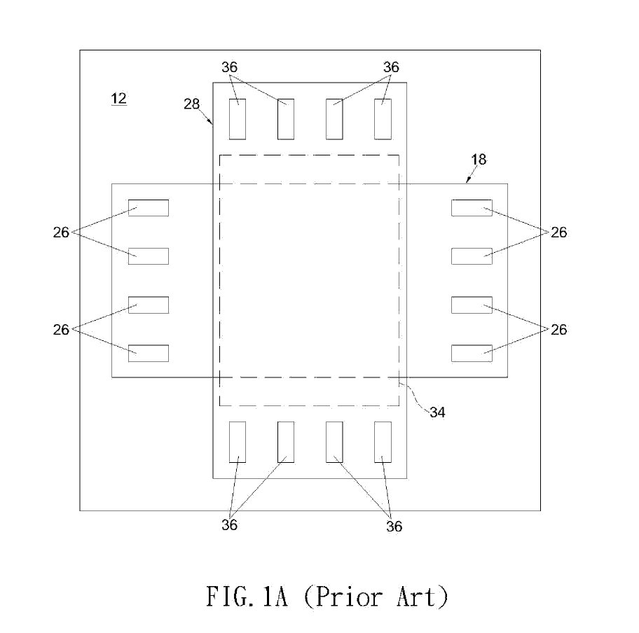

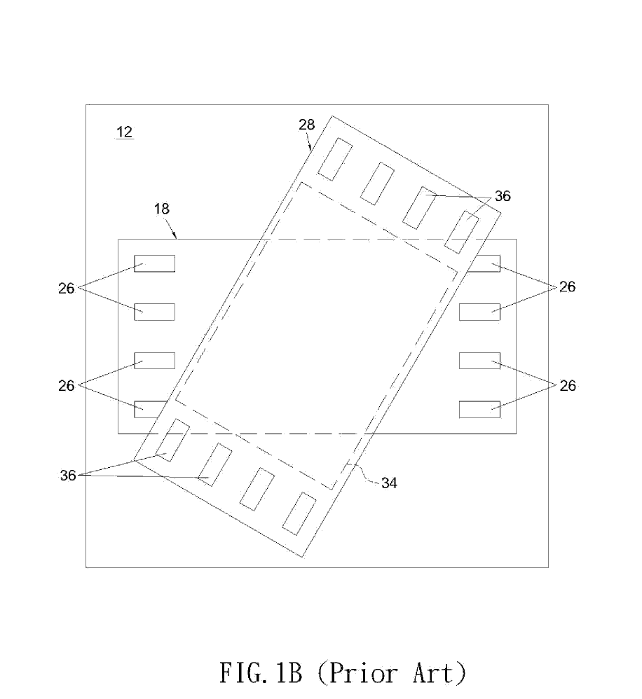

### DESCRIPTION OF THE PREFERRED EMBODIMENT

The detailed description of the present invention will be discussed in the following embodiments, which are not intended to limit the scope of the present invention, but can be adapted for other applications. While drawings are illustrated in details, it is appreciated that the quantity of the disclosed components may be greater or less than that disclosed, except expressly restricting the amount of the components.

In the semiconductor package process, the wafer finished the front end process is to do the thinning process to thin the thickness of the wafer to 2˜20 mil. The wafer is coating or printing a polymer material on the reverse surface of the wafer. The polymer material is a resin, especially is a B-stage resin. After a baking or illuminating process, the polymer material is in semi-solid glue state with stickiness. A removable tape is used to stick on the polymer material. Therefore, the wafer is in sawing process and cut into a plurality of chips. Finally, each of the chips is connected to the substrate and the chips are formed a chips stacked structure.

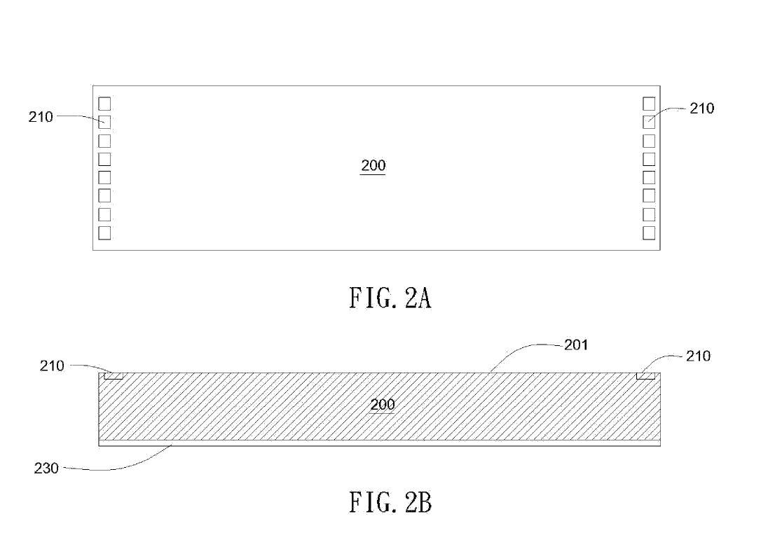

Please refer to FIG. 2; it is a top view of the stacked package structure in the present invention. As shown in FIG. 2, there is a substrate 100 provided in the present invention. The substrate 100 includes a top surface and a bottom surface. The top surface including a plurality of metal terminals 110 disposed thereon. The substrate 100 is a printed circuit board (PCB). When the substrate 100 is a PCB, the substrate is able to be a ball grid array (BGA) carrier board. The substrate 100 in the present embodiment includes a plurality of metal channels (not shown). The metal channels are used to connect the metal terminals 110 on the top surface of the substrate and the metal pads (not shown) on the bottom surface of the substrate. Therefore, the solder bump or gold bump can be used in the bottom surface of the substrate to form an array layout.

Still referring to FIG. 2, the chips stacking steps are continuing to process. It should be noted that there are a plurality of chips with similar sizes stacked on the substrate and then the wire bonding process is used to electrically connect the chips and the substrate. Therefore, in the present embodiment, the longer end on the active surface 201 of the chips 200 includes a plurality of bonding pads 210 disposed thereon. Besides, the bottom surface of the chip 200 includes an adhesive layer 230. The adhesive layer is a polymer material, such as a B-stage resin. The adhesive layer also can be a tape, it is not limited herein. In addition, the adhesive layer is an isolated layer, as shown in FIG. 2B.

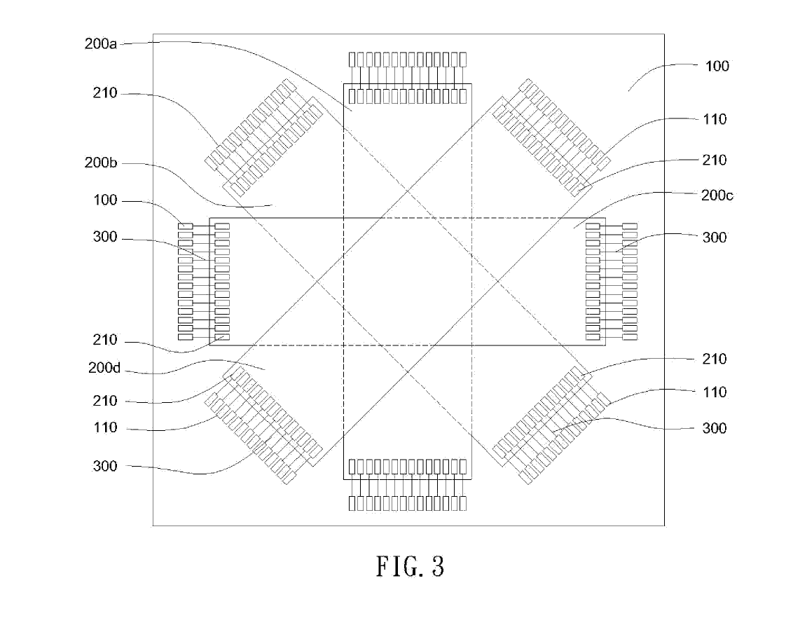

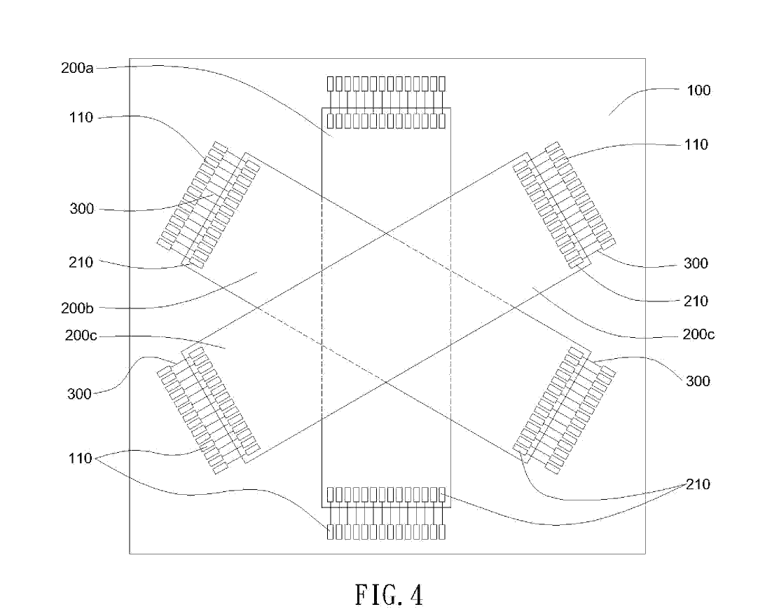

Now referring to FIG. 3, it is top view showing a preferred embodiment of the present invention. At first, a chip 200a is stuck on the substrate 100 and exposing the metal terminals 110. An adhesive layer 230 is used to connect the chip 200a and the substrate 100 on the bottom surface of the chip 200a. The geometrical relationship between the chip 200a and the substrate 100 is the four edges of the chip 200a are paralleled to the four edges of the substrate or there is a rotational angle between the four edges of the chip 200a and the four edges of the substrate. There is no limitation in the present invention. In the present embodiment, the four edges of the chip 200a and the four edges of the substrate 100 are parallel. Now, the stacking step for another chip 200b is processing. The chip 200b is stacked on the active surface of the chip 200a by an adhesive layer with a rotational angle and the metal terminals 110 and the bonding pads 210 on the chip 200a are exposed. Subsequently, another chip 200c is stacked on the chip 200b. The chip 200c is stacked on the active surface of the chip 200b with a rotation angle by the adhesive layer. The corresponding metal terminals 110, the chip 200a and the bonding pads of the chip 200b are exposed. Finally, the chip 200d is stacked on the chip 200c. The chip 200d is stacked on the active surface of the chip 200c with a rotational angle by the adhesive layer and the corresponding metal terminals 110, the chip 200a, the chip 200b and the bonding pads 210 of the chip 200c are exposed.

Obviously, during the stacking process of the present invention, the chips with the same sizes are stacked to each other with a rotation angle on the substrate. Therefore, the bonding pads on each of the chips are exposed. After the stacking process of the chips was done, a wire bonding process is used to electrically connect the chips and the substrate. In the present embodiment, the relationship between the rotation angle of the chips and the number of the stacked chips is 180/chips. In the present embodiment, there are four chips (200a-200d) stacked, so the angle between the edge of the upper chip (such as chip 200b) and the edge of the lower chip (such as chip 200a) is 45 degree. So when the chip is wider (the chip is thinner), the number of the chips are able to be stacked are increased. Besides, it should be noted that the rotational method to stack the chips is one of the reasons. Because the chips are stacked by a rotational method, the contact area between the upper chip and the lower chip is increased. The connection between the upper chip and the lower chip is better. The chips are separated in the molding process can be avoided during the following package processes. In the preferred embodiment of the present invention, each of the chips is stacked with a rotational angle is 45 degree.

After stacking the chips, the baking step is processed. The adhesive layer 230 is solidified. Then the wire bonding is used to electrically connect the chips and the substrate 100. Because the bonding pads 210 are exposed on the stacked chips of the substrate 100, one time wire bonding procedure is used. As shown in FIG. 3, the metal wires 300 are used to connect the bonding pads 210 on the chips (200a, 200b, 200c, and 200d) and the metal terminals 100 of the substrate 100. Because the method of connecting the metal wires 300 is not the main object of the present invention, the description of the connection of the metal wires 300 is omitted. Also, when the wire bonding process is in executing, which chip is the first chip to start the wire bonding is not limited herein.

After wire bonding step was done, the molding procedure is used to cover the top surface of the substrate 100, the stacked chips 200 and the metal wires 300 in accordance with an encapsulated material formed by a polymer material (not shown). Therefore, there are some solder balls implanted on the bottom surface of the substrate 100. After the reflow process, a multi chips stacked package procedures are done.

In another embodiment of the present invention, as shown in FIG. 4, a substrate 100 includes a top surface and a bottom surface. The around area of the top surface of the substrate 100 includes a plurality of metal terminals 110 disposed thereon. The bottom surface of the substrate 100 includes a plurality of bonding pads (not shown). Each of the bonding pads is corresponding and electrically connected to each of the metal terminals 110. The adhesive layer on the bottom surface is used to connect the chip 200a on the top surface of the substrate 100 where the region is closed to the central region and exposing the metal ends on the around area on the top surface. The two longer edges of the chip 200a include a plurality of metal bonding pads 210. In this embodiment, the four edges of the chip 200a are paralleled to the four edges of the substrate. Now, the chip 200b is stacked on the active surface of the chip 200a by an adhesive layer with a rotational angle, and the metal terminals 110 and the bonding pads 210 on the chip 200a are exposed. The two longer edges of the chip 200b also include the metal pads. In this embodiment, the chip 200b is rotated to left direction (also called negative rotational angle) to stack on the active surface of the chip 200a. For example, in the present embodiment, the rotation angle between the chip 200a and the chip 200b is 60 degree. Subsequently, another chip 200c is stacked on the chip 200b. The chip 200c is stacked on the active surface of the chip 200b with a rotation angle by the adhesive layer. The bonding pads 210 of the chip 200a and the chip 200b are exposed. The two longer edges of the chip 200c also include the metal pads. The rotation angle between the chip 200a and the chip 200b is 60 degree. Obviously, it should be noted that the rotation angle between the chip 200a and the chip 200c is also 60 degree. It is satisfied that the relationship of the rotational angle between the chips and the number of chips is 180 degree/chips.

After stacking the chips 200a, 200b and 200c on the top surface of the substrate 100, the baking step is processed. The adhesive layer 230 is solidified. Then the wire bonding is used to electrically connect the chips and the substrate 100. Because the bonding pads 210 are exposed on the stacked chips of the substrate 100, one time wire bonding procedure is used. The metal wires 300 are used to connect the bonding pads 210 on the chips (200a, 200b, 200c, and 200d) and the metal ends 100 of the substrate 100. After wire bonding process was done, the molding procedure is used to cover the top surface of the substrate 100, the stacked chips (200a, 200b, and 200c) and the metal wires 300 in accordance with an encapsulated material, as shown in FIG. 4. Besides, in the present embodiment, the chip 200b is able to rotate in the right direction (also called position rotational angle) to stack the chips, there is no limitation in the present invention.

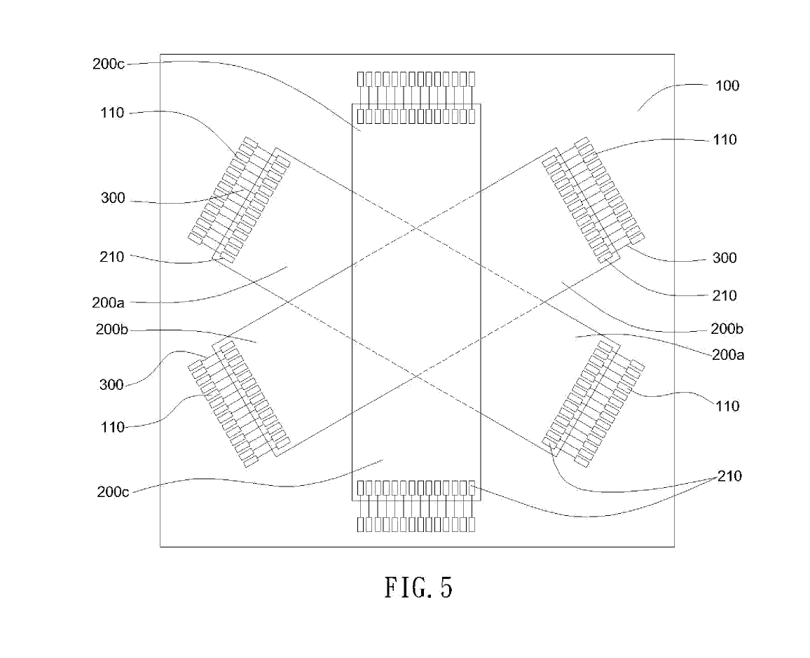

There is another embodiment provided in the present invention, as shown in FIG. 5, the different between this embodiment and the embodiment shown in FIG. 4 is that the chip 200a is fixed on the first surface of the substrate 100 by the adhesive layer on the bottom surface with a rotation angle. As shown in FIG. 5, the rest of the chips 200b and 200c are stacked by the procedure described in FIG. 4, so the description for stacking the chips 200b and 200c is omitted.

What is claimed is:

1. A multi-chips stacked package structure comprising:
a substrate having a top surface including a plurality of metal terminals disposed thereon, and a bottom surface including a plurality of metal pads and each of the metal terminals is electrically connected to each of the metal pads;
a first chip connected in the center region of the top surface of the substrate by an adhesive layer and the end region of the top surface is exposed, and the longer two ends of the first chip includes a plurality of bonding pads;
a second chip stacked on the first chip by the adhesive layer with a rotational angle and the metal pads of the first chip are exposed and the second chip includes a plurality of bonding pads;
a third chip stacked on the second chip by the adhesive layer with a rotational angle and the metal pads of the first chip and the second chip are exposed and the third chip includes a plurality of bonding pads;
a forth chip stacked on the third chip by the adhesive layer with a rotational angle and the metal pads of the first chip, the second chip and the third chip are exposed and the four chip includes a plurality of bonding pads;
a plurality of conductive wires used to electrically connect the bonding pads of the first chip, the second chip, the third chip and the forth chip and the metal terminals; and
an encapsulated material used to cover the conductive wires on the first chip, the second chip, the third chip and the forth chip and the surface of the substrate.

2. The package structure of claim 1, wherein the metal pads of the bottom surface of the substrate is electrically connected to a plurality of metal balls.

3. The package structure of claim 1, wherein the longer end of the first chip is paralleled to the edge of the substrate.

4. The package structure of claim 1, wherein the longer end of the first chip and the extended line of the edge of the substrate are formed a rotational angle.

5. The package structure of claim 1, wherein the rotational angel between the first chip and the second chip is 45 degree.

6. The package structure of claim 1, wherein the adhesive layer is a tape.

7. A multi-chips stacked package structure comprising:
a substrate having a top surface including a plurality of metal terminals disposed thereon, and a bottom surface including a plurality of metal pads and each of the metal terminals is electrically connected to each of the metal pads;
a first chip connected in the center region of the top surface of the substrate by an adhesive layer and the end region of the top surface is exposed, and the longer two ends of the first chip includes a plurality of bonding pads;
a second chip stacked on the first chip by the adhesive layer with a rotational angle and the metal pads of the first chip are exposed and the second chip includes a plurality of bonding pads;
a third chip stacked on the second chip by the adhesive layer with a rotational angle and the metal pads of the first chip and the second chip are exposed and the third chip includes a plurality of bonding pads;
a plurality of conductive wires used to electrically connect the bonding pads of the first chip, the second chip and the third chip and the metal terminals; and
an encapsulated material used to cover the conductive wires on the first chip, the second chip, the third chip and the top surface of the substrate;
wherein the rotational angle is based on the central line of the first chip.

8. The package structure of claim 7, wherein the metal pads of the bottom surface of the substrate is electrically connected to a plurality of metal balls.

9. The package structure of claim 7, wherein the longer end of the first chip is paralleled to the edge of the substrate.

10. The package structure of claim 7, wherein the longer end of the first chip and the extended line of the edge of the substrate are formed a rotational angle.

11. The package structure of claim 7, wherein the adhesive layer is a tape.

12. The package structure of claim 7, wherein the rotational angel between the first chip and the second chip is 60 degree.

13. A multi-chips stacked package structure comprising:
a substrate having a top surface that including a plurality of metal terminals disposed thereon, and a bottom surface including a plurality of metal pads and each of the metal terminals is electrically connected to each of the metal pads;
a plurality of chips, the width of each of the chips is the same and the two longer ends of the chip includes a plurality bonding pads, each of the chips is stacked on the other chip by an adhesive layer with a rotational angle and the metal pads of the chips are exposed and the bonding pads on each of the chips are exposed;
a plurality of conductive wires used to electrically connect the bonding pads of the first chip, the second chip and the third chip and the metal terminals; and
an encapsulated material used to cover the conductive wires on the first chip, the second chip, the third chip and the top surface of the substrate.

14. The package structure of claim 13, wherein the metal pads on the bottom surface of the substrate are electrically connected to a plurality of metal balls.

15. The package structure of claim 13, wherein the adhesive layer is a tape.

16. The package structure of claim 13, wherein the rotational angel between the first chip and the second chip is 180 degree.
